(19) United States
(12) Patent Application Publication
(10) Pub. No.: US 2025/0072068 A1
(43) Pub. Date: Feb. 27, 2025

(54) STACKED STRUCTURE, FABRICATION METHOD OF THE STACKED STRUCTURE, AND SEMICONDUCTOR DEVICE INCLUDING THE STACKED STRUCTURE

(71) Applicant: Japan Display Inc., Minato-ku (JP)

(72) Inventor: Masumi NISHIMURA, Tokyo (JP)

(73) Assignee: Japan Display Inc., Minato-ku (JP)

(21) Appl. No.: 18/948,697

(22) Filed: Nov. 15, 2024

Related U.S. Application Data
(63) Continuation of application No. PCT/JP2023/014647, filed on Apr. 11, 2023.

(30) Foreign Application Priority Data
May 24, 2022 (JP) 2022-084441

(51) Int. Cl. H01L 29/06; H01L 21/02; H01L 29/20; H01L 31/0304; H01L 33/32

(52) U.S. Cl. CPC H01L 29/0692; H01L 21/02631; H01L 29/2003; H01L 31/03044; H01L 33/32

(57) ABSTRACT

Disclosed is a stacked structure which may include a buffer layer, a first semiconductor layer, and a second semiconductor layer. The buffer layer and the first semiconductor layer are stacked with each other in a vertical direction. The second semiconductor layer is in contact with a side surface of the first semiconductor layer and may surround at least a part of the first semiconductor layer in a plane perpendicular to the vertical direction. Each of the first semiconductor layer and the second semiconductor layer may include a Group III-V material or a Group III nitride material. Crystallinity of the first semiconductor layer may be higher than crystallinity of the second semiconductor layer. The buffer layer may be exposed from the second semiconductor layer in the vertical direction.

### CROSS-REFERENCE TO RELATED APPLICATIONS

This application is a Continuation of International Patent Application No. PCT/JP2023/014647, filed on Apr. 11, 2023, which claims the benefit of priority to Japanese Patent Application No. 2022-084441, filed on May 24, 2022, the entire contents of which are incorporated herein by reference.

### FIELD

An embodiment of the present invention relates to a stacked structure, a method for fabricating the same, and a semiconductor device including the stacked structure.

### BACKGROUND

In recent years, there has been active development of semiconductor devices utilizing Group III-V materials or Group III nitride materials as semiconductors. In particular, inorganic materials containing gallium nitride (hereinafter, referred to as gallium nitride-based materials) have a large band gap as well as a high breakdown electric field and saturation drift velocity compared with other semiconductor materials such as silicon and oxide semiconductors. For this reason, the use of gallium nitride-based materials in an active layer provides a possibility to realize semiconductor devices with excellent characteristics, and much attention has been paid to gallium nitride-based materials (see, for example, International Patent Application Publication No. 2017/155032).

### SUMMARY

At least one of the embodiments of the present invention is a stacked structure. The stacked structure includes a buffer layer, a first semiconductor layer, and a second semiconductor layer. The buffer layer and the first semiconductor layer are stacked with each other in a vertical direction. The second semiconductor layer is in contact with a side surface of the first semiconductor layer and surrounds at least a part of the first semiconductor layer in a plane perpendicular to the vertical direction. Each of the first semiconductor layer and the second semiconductor layer includes a Group III-V material or a Group III nitride material. Crystallinity of the first semiconductor layer is higher than crystallinity of the second semiconductor layer. The buffer layer is exposed from the second semiconductor layer in the vertical direction.

At least one of the embodiments of the present invention is a semiconductor device including a stacked structure. The stacked structure includes a buffer layer, a first semiconductor layer, and a second semiconductor layer. The buffer layer and the first semiconductor layer are stacked with each other in a vertical direction. The second semiconductor layer is in contact with a side surface of the first semiconductor layer and surrounds at least a part of the first semiconductor layer in a plane perpendicular to the vertical direction. Each of the first semiconductor layer and the second semiconductor layer includes a Group III-V material or a Group III nitride material. Crystallinity of the first semiconductor layer is higher than crystallinity of the second semiconductor layer. The buffer layer is exposed from the second semiconductor layer in the vertical direction.

At least one of the embodiments of the present Invention is a fabrication method of a stacked structure. The fabrication method includes forming a buffer layer over a substrate, forming, over the buffer layer, a semiconductor layer containing gallium nitride so as to cover the buffer layer, and etching the semiconductor layer. The semiconductor layer is etched so as to leave a first portion overlapping the buffer layer in a vertical direction and a second portion which does not overlap the buffer layer.

### BRIEF DESCRIPTION OF DRAWINGS

FIG. 1A is a schematic top view of a stacked structure according to an embodiment of the present invention.

FIG. 1B is a schematic cross-sectional view of a stacked structure according to an embodiment of the present invention.

FIG. 2A is a schematic cross-sectional view of a stacked structure according to an embodiment of the present invention.

FIG. 2B is a schematic cross-sectional view of a stacked structure according to an embodiment of the present invention.

FIG. 3A is a schematic cross-sectional view of a stacked structure according to an embodiment of the present invention.

FIG. 3B is a schematic cross-sectional view of a stacked structure according to an embodiment of the present invention.

FIG. 3C is a schematic cross-sectional view of a stacked structure according to an embodiment of the present invention.

FIG. 4 is a schematic cross-sectional view of a stacked structure according to an embodiment of the present invention.

FIG. 5A is a schematic cross-sectional view showing a fabrication method of a stacked structure according to an embodiment of the present invention.

FIG. 5B is a schematic cross-sectional view showing a fabrication method of a stacked structure according to an embodiment of the present invention.

FIG. 5C is a schematic cross-sectional view showing a fabrication method of a stacked structure according to an embodiment of the present invention.

FIG. 5D is a schematic cross-sectional view showing a fabrication method of a stacked structure according to an embodiment of the present invention.

FIG. 6A is a schematic cross-sectional view showing a fabrication method of a stacked structure according to an embodiment of the present invention.

FIG. 6B is a schematic cross-sectional view showing a fabrication method of a stacked structure according to an embodiment of the present invention.

FIG. 7A is a schematic cross-sectional view of a semiconductor device according to an embodiment of the present invention.

FIG. 7B is a schematic top view of a semiconductor device according to an embodiment of the present invention.

FIG. 8A is a schematic cross-sectional view of a semiconductor device according to an embodiment of the present invention.

FIG. 8B is a schematic cross-sectional view of a semiconductor device according to an embodiment of the present invention.

### DESCRIPTION OF EMBODIMENTS

Hereinafter, each embodiment is explained with reference to the drawings. The present disclosure can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, the drawings are only an example, and do not limit the interpretation of the present disclosure including embodiments thereof. In the specification and the drawings, the same reference number is provided to an element that is the same as that which appears in preceding drawings, and a detailed explanation may be omitted as appropriate. The reference number is used when plural structures which are the same as or similar to each other are collectively represented, while a hyphen and a natural number are further used when these structures are independently represented.

In the specification and the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

In the specification and the claims, an expression “a structure is exposed from another structure” means a mode in which a part of the structure is not covered by the other structure and includes a mode where the part uncovered by the other structure is further covered by another structure. In addition, a mode expressed by this expression includes a mode where a structure is not in contact with other structures.

In the embodiments of the present invention, when a plurality of films is formed with the same process at the same time, these films have the same layer structure, the same material, and the same composition. Hence, the plurality of films is defined as existing in the same layer.

### First Embodiment

In this embodiment, the structure of the stacked structure 100 and a fabrication method thereof according to an embodiment of the present invention are explained.

### 1. Structure of Stacked Structure

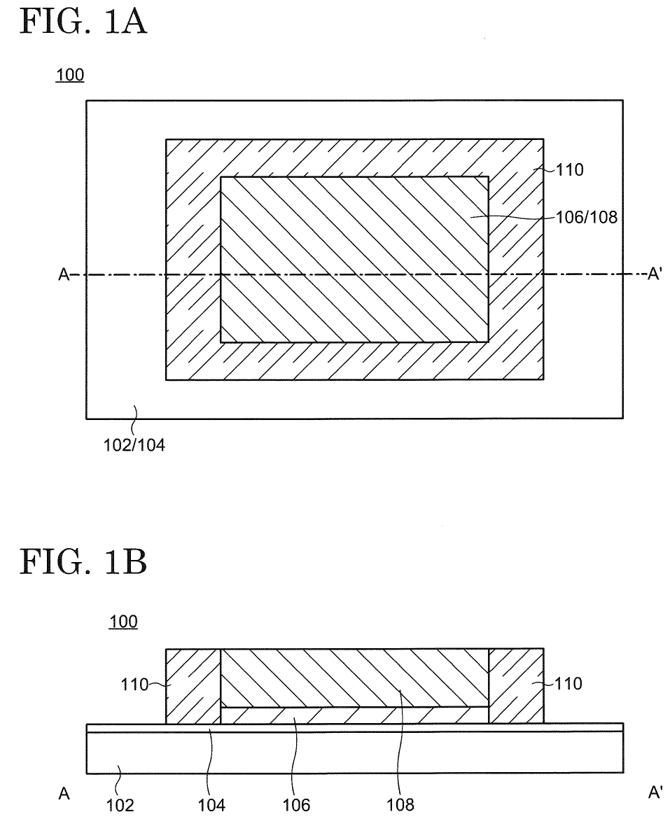

A schematic top view of the stacked structure 100 is shown in FIG. 1A, and a schematic view of a cross section along the chain line A-A′ in FIG. 1A is shown in FIG. 1B. As shown in these drawings, the stacked structure 100 includes a buffer layer 106, a first semiconductor layer 108, and a second semiconductor layer 110 as its fundamental components. The stacked structure 100 may be provided over a substrate 102, and an undercoat 104 may be provided between the stacked structure 100 and the substrate 102 as an optional component. As described in detail below, the first semiconductor layer 108 and the second semiconductor layer 110 include a Group III-V material or a Group III nitride material. In the present embodiment, explanations are provided using a gallium nitride-based material as an example of a Group III-V material or a Group Ill nitride material.

### 1-1. Buffer Layer

The buffer layer 106 functions to promote crystallization of the first semiconductor layer 10 formed thereover and may include a metal such as titanium, aluminum, silver, nickel, copper, strontium, rhodium, palladium, iridium, platinum, and gold, a metal nitride such as titanium nitride, or a metal oxide such as zinc oxide. Since these elements or compounds are conductive, the buffer layer 106 is also capable of functioning as an electrode.

Preferably, a material having a hexagonal-most-dense structure or a structure equivalent thereto which is a crystal structure in which the c-axis is not orthogonal at 90° to the a-axis and the b-axis, as exemplified by titanium, zinc oxide, and the like is used. The formation of the buffer layer 106 with such a material allows the c-axis of the buffer layer 106 to orient perpendicular or almost perpendicular to the surface over which the buffer layer 106 is provided (the surface of the substrate 102 in the example shown in FIG. 1A and FIG. 1B). On the other hand, it is known that the gallium nitride-based material contained in the first semiconductor layer 108 takes a hexagonal crystal structure such as the wurtzite type structure and undergoes crystal growth in the c-axis direction to minimize its surface energy. Therefore, when the buffer layer 106 is configured with a material containing a hexagonal-most-dense structure or a structure equivalent thereto and the first semiconductor layer 108 containing a gallium nitride-based material is formed so as to overlap the buffer layer 106, the first semiconductor layer 108 is affected by the crystal structure of the buffer layer 106 and undergoes crystal growth in the c-axis direction. As a result, the first semiconductor layer 108 is able to have a highly crystalline c-axis orientation.

It is preferable that the surface of the buffer layer 106 have high planarity in view of more effective crystal growth of the first semiconductor layer 108 in the c-axis direction. Specifically, the arithmetic mean roughness (Ra) of the surface of the buffer layer 106 is preferred to be smaller than 2.3 nm. The root mean square roughness (Rq) of the surface of the buffer layer 106 is preferred to be smaller than 2.9 nm. It is preferred that the thickness of the buffer layer 106 be equal to or less than 50 nm to obtain high surface flatness, and the buffer layer 106 is formed with a thickness equal to or greater than 10 nm and equal to or less than 50 nm, for example.

### 1-2. First Semiconductor Layer and Second Semiconductor Layer

Both the first semiconductor layer 108 and the second semiconductor layer 110 contain a Group III-V material or a Group III nitride material. Here, a gallium nitride-based material is used for explanation. The gallium nitride-based material includes a semiconductor containing nitrogen and gallium such as gallium nitride (GaN) and aluminum gallium nitride (AlGaN). The composition ratio of nitrogen and gallium may deviate from the stoichiometric composition. The first semiconductor layer 108 and the second semiconductor layer 110 may further include other elements. For example, the first semiconductor layer 108 and the second semiconductor layer 110 may each contain one or a plurality of elements such as silicon, germanium, magnesium, zinc, cadmium, beryllium, indium, aluminum, and arsenic. The addition of these elements enables valence electron control of the first semiconductor layer 108 and the second semiconductor layer 110, by which not only can the intrinsic property (i-type) be maintained but also the band gap can be controlled and the p-type or n-type conductivity can be imparted.

As shown in FIG. 1A and FIG. 1B, the first semiconductor layer 108 is located over the buffer layer 106 and is in contact with the top surface of the buffer layer 106. On the other hand, the second semiconductor layer 110 does not contact the top surface of the buffer layer 106 and does not overlap the buffer layer 106. That is, the buffer layer 106 is exposed from the second semiconductor layer 110 in the vertical direction. The second semiconductor layer 110 is in contact with the side surface of the buffer layer 106 and surrounds at least a part or the whole of the first semiconductor layer 108 in a plane perpendicular to the vertical direction. Therefore, as described above, the first semiconductor layer 108 is greatly affected by the crystal structure of the buffer layer 106, and crystal growth occurs preferentially in the c-axis direction during formation. However, the second semiconductor layer 110 is less affected by the crystal structure of the buffer layer 106 than the first semiconductor layer 108. Therefore, the crystallinity of the first semiconductor layer 108 is higher than that of the second semiconductor layer 110. For example, the first semiconductor layer 108 results in a sharper (smaller half-width) peak compared with the second semiconductor layer 110 in an electron beam analysis.

The thicknesses of the first semiconductor layer 108 and the second semiconductor layer 110 are set as appropriate according to the application of the stacked structure 100. However, the first semiconductor layer 108 and the second semiconductor layer 110 are simultaneously fabricated as described below. Therefore, the compositions and the thicknesses of the first semiconductor layer 108 and the second semiconductor layer 110 may be identical or substantially identical to each other.

### 1-3. Substrate and Undercoat

There are no restrictions on the material contained in the substrate 102. For example, an amorphous glass substrate, a quartz substrate, a sapphire substrate, a silicon substrate, or a substrate containing a polymer such as a polyimide, a polyamide, or an acrylic resin may be used as the substrate 102. Alternatively, a metal substrate such as a stainless steel substrate may be used. There is also no restriction on the crystallinity of the substrate 102, and either a single-crystal substrate or an amorphous substrate may be used. The substrate 102 may be flexible.

The undercoat 104, which is an optional component, is an electrically insulating film and may include, for example, a silicon-containing inorganic compound such as silicon nitride and silicon oxide as well as aluminum oxide. The undercoat 104 may have a single layer structure or may be composed of a plurality of layers of different compositions. For example, a stack of a film containing silicon oxide and a film containing silicon nitride may be used as the undercoat 104.

### 2. Modified Example

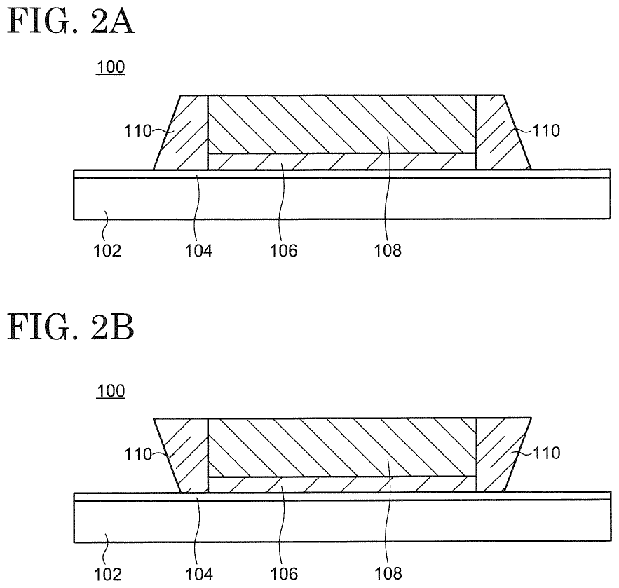

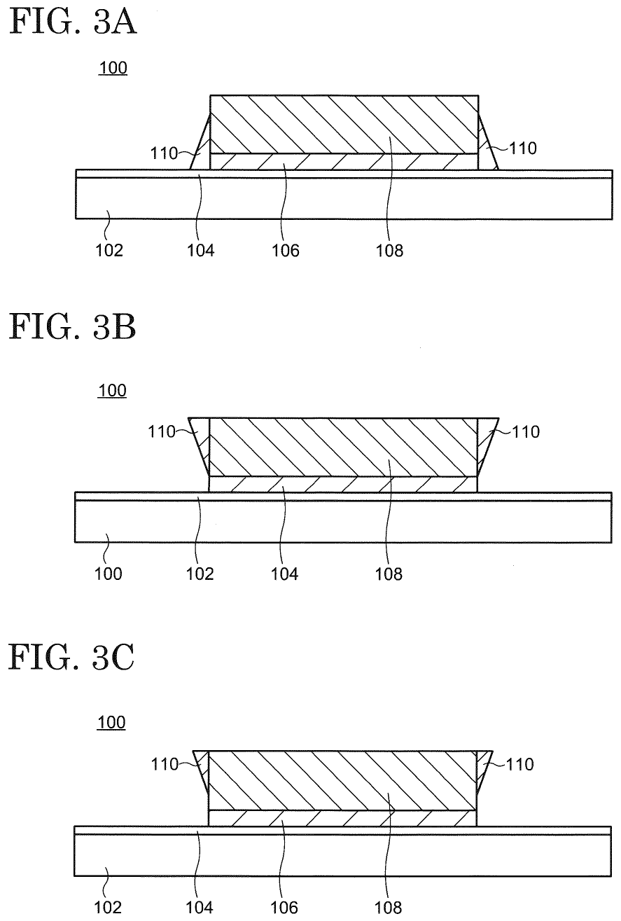

The structure of the stacked structure 100 is not limited to the aforementioned structure. For example, the second semiconductor layer 110 may have a tapered shape as shown in FIG. 2A and FIG. 2B. That is, the side of the second semiconductor layer 110 spaced away from the first semiconductor layer 108 may be inclined from the vertical direction. In this case, the thickness of the second semiconductor layer 110 may decrease (FIG. 2A) or increase (FIG. 2B) in a plane perpendicular to the vertical direction as the distance from the first semiconductor layer 108 increases. Alternatively, part or the whole of the side surface of the first semiconductor layer 108 may be exposed from the second semiconductor layer 110 as shown in FIG. 3A and FIG. 3C. Alternatively, part or the whole of the side surface of the buffer layer 106 may be exposed from the second semiconductor layer 110 as shown in FIG. 3B and FIG. 3C. The shape of the second semiconductor layer 110 can be controlled by appropriately adjusting the etching conditions.

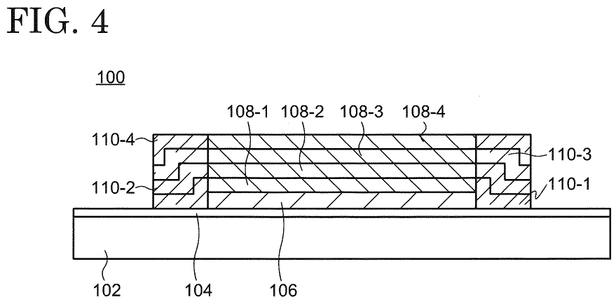

In the stacked structure 100, both the first semiconductor layer 108 and the second semiconductor layer 110 may have a single layer structure or may be formed with a plurality of layers as shown in FIG. 4. When stacking a plurality of layers, there is no restriction on the number of layers, and the number of layers may be selected from a range equal to or greater than 2 and equal to or less than 10, for example. In the example demonstrated in FIG. 4, the first semiconductor layer 108 is composed of semiconductor layers 108-1, 108-2, 108-3, and 108-4, and the second semiconductor layer 110 is also composed of semiconductor layers 110-1, 110-2, 110-3, and 110-4. When stacking a plurality of layers, the composition of each layer may be changed as appropriate so that the conductivity differs between the layers. For example, each of the first semiconductor layer 108 and the second semiconductor layer 110 may be composed of a semiconductor layer including p-type gallium nitride, a semiconductor layer including p-type aluminum gallium nitride, a semiconductor layer including an n-type gallium nitride, and a semiconductor layer including an n-type aluminum gallium nitride as appropriate. As described above, the first semiconductor layer 108 and the second semiconductor layer 110 are simultaneously formed in the same process. Accordingly, the stacking structure of the first semiconductor layer 108 and the second semiconductor layer 110 may also be the same. For example, the number, composition, and thickness of the stacked layers may be the same between the first semiconductor layer 108 and the second semiconductor layer 110.

### 3. Fabrication Method of Stacked Structure

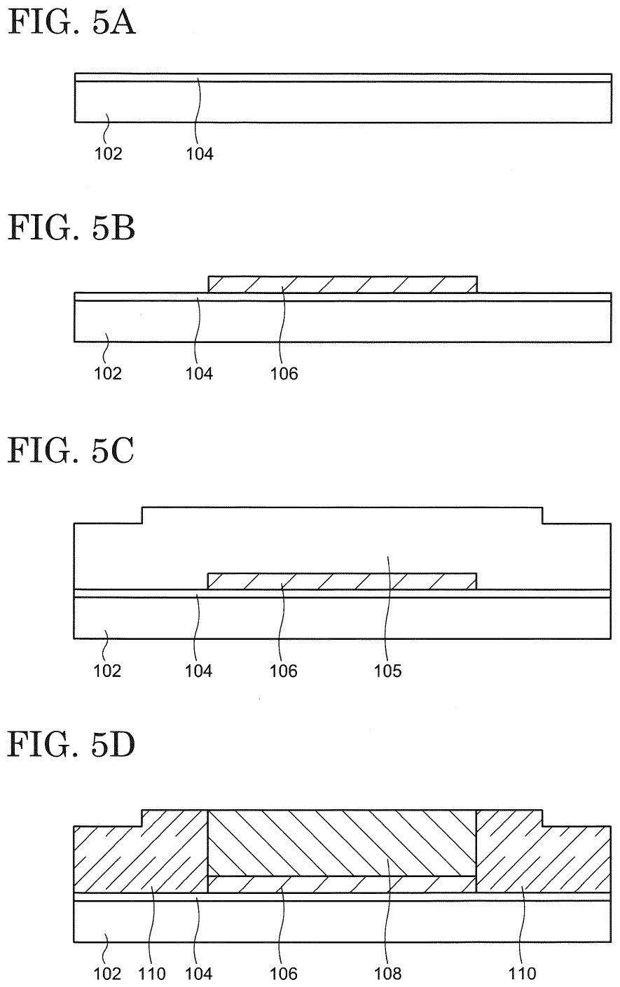

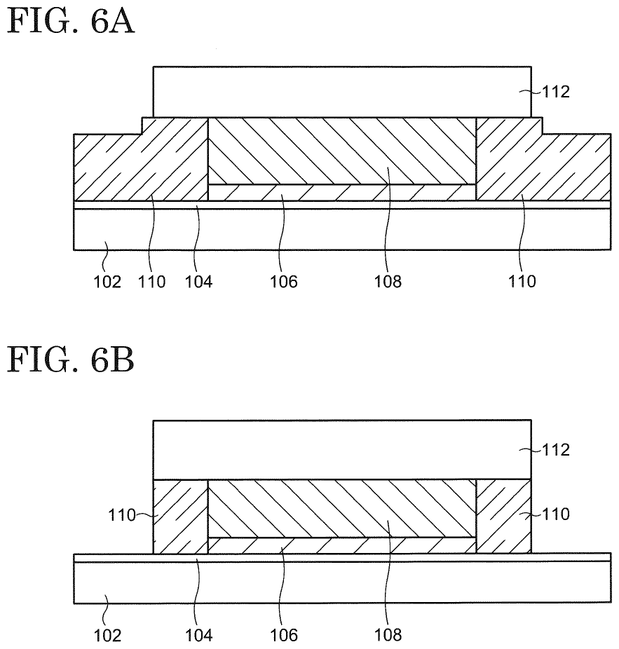

Hereinafter, an example of the fabrication method of the stacked structure 100 shown in FIG. 1A and FIG. 1B is explained using FIG. 5A through FIG. 6B.

First, the undercoat 104 is formed over the substrate 102 (FIG. 5A). The undercoat 104 may be formed by applying a chemical vapor deposition (CVD) method or a sputtering method. Alternatively, when a silicon substrate or a metal substrate is used, an oxide layer formed by oxidizing the surface may be used as the undercoat 104. In this case, a layer containing a silicon-containing inorganic compound or the like may be further stacked over the oxide layer. This process is not necessary when the undercoat 104 is not provided.

The buffer layer 106 is then formed over the substrate 102 either directly or through the undercoat 104 (FIG. 5B). The buffer layer 106 may be formed by a sputtering method using a target containing the metal to be contained in the buffer layer 106. Alternatively, the buffer layer 106 may be formed using an evaporation method or a CVD method. Patterning of the buffer layer 106 is performed by applying known photolithography.

Next, the first semiconductor layer 108 and the second semiconductor layer 110 are simultaneously formed. Specifically, a sputtering method using a sintered body of gallium nitride as a sputtering target is applied to form a semiconductor layer 105 containing a gallium nitride-based material over the top surface of the substrate 102 (FIG. 5C). The sputtering method may include a two-pole sputtering method, a magnetron sputtering method, a dual magnetron sputtering method, an opposed target sputtering method, an ion beam sputtering method, and an inductively coupled plasma (ICP) sputtering method. When the substrate 102 is an amorphous glass substrate, the semiconductor layer 105, which is transformed into the first semiconductor layer 108 and the second semiconductor layer 110, may be deposited over the buffer layer 106 with a sputtering method at a temperature equal to or lower than 600° C. This process enables the formation of the semiconductor devices described below including the stacked structure 100 over a large amorphous glass substrate at a low cost.

At this time, the semiconductor layer 105 is formed so as to cover the buffer layer 106. That is, the semiconductor layer 105 is formed to allow the entire top surface of the buffer layer 106 to overlap the semiconductor layer 105 so that the buffer layer 106 is not exposed from the semiconductor layer 105. As described above, the c-axis of the buffer layer 106 is oriented in a direction perpendicular or substantially perpendicular to the surface over which the buffer layer 106 is provided (here, the surface of the substrate 102 or the undercoat 104). Therefore, the crystal structure of the buffer layer 106 promotes the crystal growth of the semiconductor layer 105 formed thereover. As a result, crystal growth in the c-axis direction is promoted in the portion of the semiconductor layer 105 overlapping the buffer layer 106 during the deposition process of the semiconductor layer 105. On the other hand, the portion of the semiconductor layer 105 which does not overlap the buffer layer 106 is less affected by the crystal structure of the buffer layer 106, and the degree of crystal growth is smaller than that of the portion overlapping the buffer layer 106. This function of the buffer layer 106 to promote crystal growth enables the simultaneous formation of the highly crystalline first semiconductor layer 108 and the second semiconductor layer 110 with lower crystallinity than the first semiconductor layer 108 (FIG. 5D). Therefore, the first semiconductor layer 108 and the second semiconductor layer 110 can exist in the same layer and have the same composition and structure.

Thereafter, patterning is performed by etching. Specifically, a resist mask 112 is formed over the first semiconductor layer 108 and the second semiconductor layer 110 as shown in FIG. 6A. The formation of the resist mask 112 may be performed by applying known methods. At this time, the shape of the resist mask 112 is determined according to the characteristics required for the stacked structure 100, but is set to cover the first semiconductor layer 108 and a portion of the second semiconductor layer 110. More specifically, the resist mask 112 is provided so that the first semiconductor layer 108 is not exposed from the resist mask 112, the entire top surface of the first semiconductor layer 108 overlaps the resist mask 112, and the portion of the resist mask 112 in contact with the second semiconductor layer 110 surrounds the first semiconductor layer 108 in a top view. In other words, the resist mask 112 is provided so that the resist mask 112 covers the buffer layer 106 and overlaps the entire top surface of the buffer layer 106, and the portion of the resist mask 112 in contact with the second semiconductor layer 110 surrounds the buffer layer 106 in a top view.

Etching is then performed on the second semiconductor layer 110 through the resist mask 112. The etching may be dry etching or wet etching. In the dry etching, a chlorine-based dry etching may be applied. A portion which is not covered by the resist mask 112 is removed by the etching. As a result, a portion of the second semiconductor layer 110 which has relatively low crystallinity and does not overlap the buffer layer 106 remains, and this portion remaining in a plane perpendicular to the vertical direction is processed into the shape surrounding at least a portion or the whole of the first semiconductor layer 108 (FIG. 6B). The resist mask 112 is then removed to result in the stacked structure 100 shown in FIG. 1A and FIG. 1B.

As described above, since the first semiconductor layer 108 has higher crystallinity than the second semiconductor layer 110, the first semiconductor layer 108 has higher etching resistance than the second semiconductor layer 110. Therefore, when the resist mask 112 is formed to expose a part of the first semiconductor layer 108 and etching is also performed on the first semiconductor layer 108, more severe etching conditions and a longer etching time are required, which may cause damage such as side etching to the first semiconductor layer 108.

In contrast, in the fabrication method of the stacked structure 100 according to an embodiment of the present invention, etching is performed through the resist mask 112 covering not only the first semiconductor layer 108 but also the second semiconductor layer 110 at the periphery thereof to leave at least a portion or the whole of the first semiconductor layer 108. That is, only the second semiconductor layer 110 is removed by etching. Hence, it is possible to select the most suitable and moderate conditions for etching the second semiconductor layer 110, thereby minimizing any damage. As a result, it is possible to fabricate the stacked structure 100 containing a gallium nitride-based material with a precisely controlled structure and properties.

### Second Embodiment

In this embodiment, a semiconductor device including the stacked structure 100 described in the First Embodiment is explained. An explanation of the structures the same as or similar to those described in the First Embodiment may be omitted.

There are no particular restrictions on the semiconductor devices including the stacked structure 100, and transistors (thin-film transistors, power transistors), light-emitting elements including laser elements, photosensors including image sensors, solar cell cells, a variety of diodes including constant voltage diodes and variable capacitance diodes, piezoelectric devices, and the like are represented as the semiconductor devices.

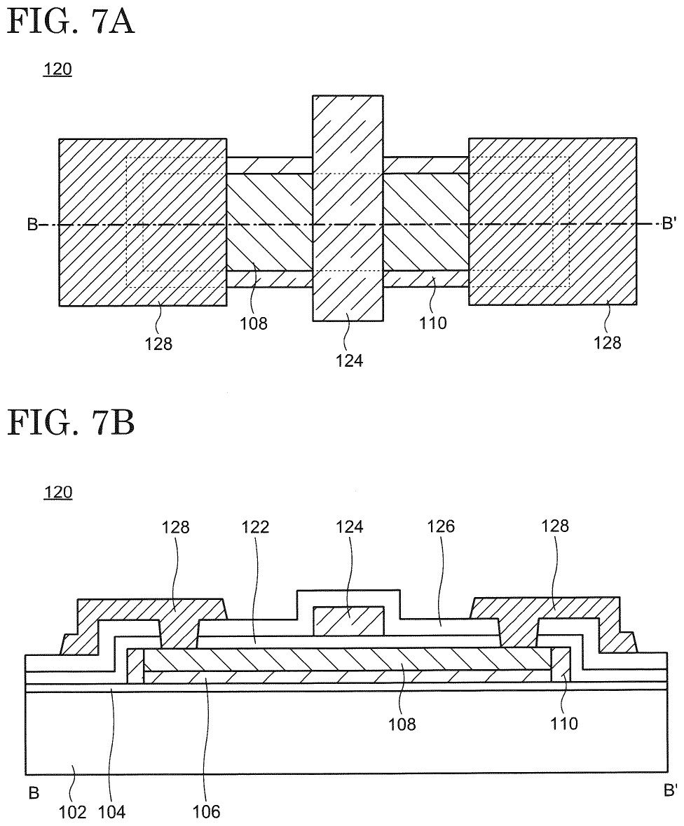

As an example, a schematic top view of a transistor 120 including the stacked structure 100 is shown in FIG. 7A, and a schematic view of a cross section along the chain line B-B′ in FIG. 7A is shown in FIG. 7B. When the stacked structure 100 is applied to a transistor, a portion of the first semiconductor layer 108 of the stacked structure 100 functions as an active layer (channel). As shown in these drawings, the transistor 120 is provided over the substrate 102 either directly or through the undercoat 104 and has the stacked structure 100 including the buffer layer 106, the first semiconductor layer 108, and the second semiconductor layer 110, a gate insulating film 122 over the stacked structure 100, a gate electrode 124 overlapping the stacked structure 100 through the gate insulating film 122, an interlayer insulating film 126 covering the gate insulating film 122, and source/drain electrodes 128 electrically connected to the first semiconductor layer 108 through openings formed in the interlayer insulating film 126. Although not illustrated, the transistor 120 may further have a protective insulating film covering the source/drain electrodes 128 and the interlayer insulating film 126. The transistor 120 shown in FIG. 7A and FIG. 7B is a so-called top-gate type transistor. Although not illustrated, the transistor 120 may be a bottom-gate type transistor or a dual-gate type transistor having a pair of gate electrodes over and below the stacked structure 100.

It is expected that the transistor 120 including the stacked structure 100 exhibits excellent characteristics especially as a power transistor due to the large band gap, the high breakdown electric field, and the large saturation drift velocity of gallium nitride-based materials. In addition, since the application of the fabrication method of the stacked structure 100 according to an embodiment of the present invention enables the precise control of the structure and characteristics of the stacked structure 100, it is also possible to realize the transistor 120 with controlled characteristics. Moreover, the formation of the stacked structure 100 over the substrate 102 containing amorphous glass with a sputtering method allows the production of semiconductor devices including the stacked structure 100 at a low cost.

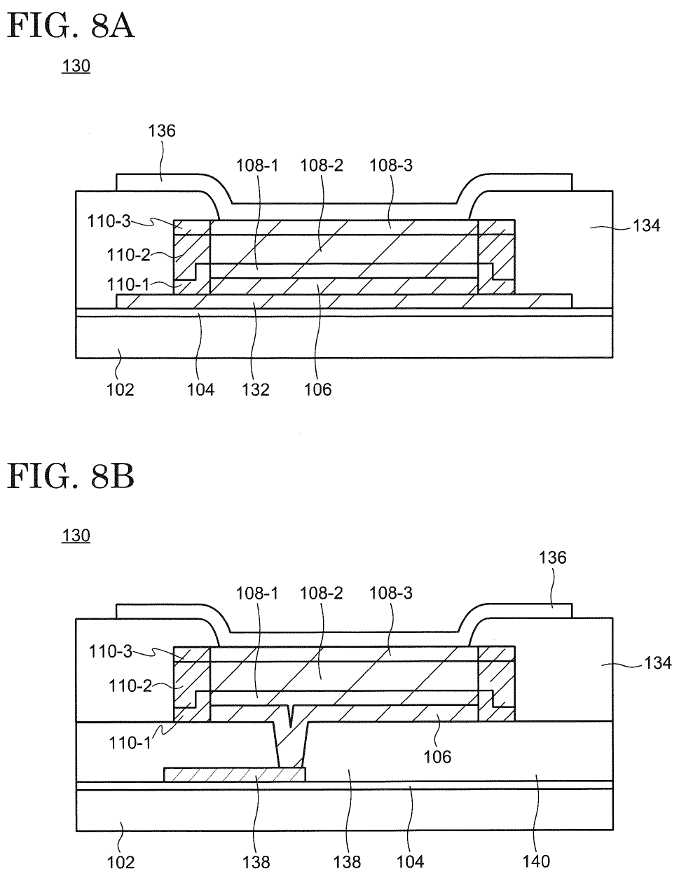

As another example, a schematic cross-sectional view of an electroluminescent light-emitting element 130 including the stacked structure 100 is shown in FIG. 8A. The light-emitting element 130 includes a lower electrode 132, the stacked structure 100 over the lower electrode 132, and an upper electrode 136 over the stacked structure 100. The light-emitting element 130 may further have an insulating film 134 covering the edge portion of the stacked structure 100. When the buffer layer 106 has conductivity, the buffer layer 106 also functions as an electrode together with the lower electrode 132.

The first semiconductor layer 108 and the second semiconductor layer 110 of the stacked structure 100 have a stacked structure suitable for recombining charges injected from the lower electrode 132 and the upper electrode 136 to convert the charges into photons. For example, the first semiconductor layer 108 and the second semiconductor layer 110 may be composed of semiconductor layers 108-1 and 110-1 containing a gallium nitride-based material having p-type conductivity, semiconductor layers 108-3 and 110-3 containing a gallium nitride-based material having n-type conductivity, and semiconductor layers 108-2 and 110-2 containing intrinsic gallium nitride or a gallium nitride-based material containing one or a plurality of elements selected from indium, aluminum, phosphorus, arsenic, and the like. In such a configuration, the semiconductor layers 108-1 and 110-1 function as an electron-transporting layer or a hole-transporting layer, the semiconductor layers 108-3 and 110-3 function as a hole-transporting layer or an electron-transporting layer, the semiconductor layers 108-2 and 110-2 function as an emission layer. Holes are injected from the lower electrode 132 through the semiconductor layers 108-1 and 110-1. Meanwhile, electrons are injected from the upper electrode 136 through the semiconductor layers 108-3 and 110-3. The electrons and holes are recombined within the semiconductor layers 108-2 and 110-2 to form an excited state, and light emission can be obtained when the excited state returns to a ground state.

In FIG. 8A, the lower electrode 132 is provided so as to overlap the second semiconductor layer 110 and is in contact with the second semiconductor layer 110. Therefore, when the lower electrode 132 has a function to promote crystallization of a layer including a gallium nitride-based material, it is preferable to provide a wiring 138 over the substrate 102 and form an insulating film 140 thereover as shown in FIG. 8B. The insulating film 140 may be formed with, for example, a polyimide, an acrylic resin, an epoxy resin, a polysiloxane resin, or the like. The insulating film 140 is provided with an opening reaching the wiring 138, and the buffer layer 106 is formed to cover this opening. This structure allows only the crystallinity of the first semiconductor layer 108 to be selectively improved, because the second semiconductor layer 110 is provided over the insulating film 140 without the function to promote the crystallization thereof. Note that the wiring 138 may be electrically connected to a semiconductor element such as a transistor provided over the substrate 102. This structure allows the light emitting element 130 to be switched on and off by the transistor.

Organic electroluminescent elements have been known as an electroluminescence type light-emitting element. Since organic electroluminescent elements include organic compounds in the electron-transporting layer, the hole-transporting layer, and the emission layer, deterioration occurs relatively quickly. On the other hand, inorganic compounds such as gallium nitride-based materials have negligibly small degradation rates compared to organic compounds. Therefore, the use of the light-emitting element 130 enables the production of a variety of light-emitting devices and display devices with high reliability. In addition, since the application of the fabrication method of the stacked structure 100 according to an embodiment of the present invention enables precise control of the structure and the characteristics of the stacked structure 100, the light emitting elements 130 with controlled characteristics as well as light emitting devices and display devices including the light emitting elements 130 can be realized.

Various modification examples are also captured by the present disclosure, including by adding or deleting a structural element or changing the design of a structural element, or by adding or omitting a step or changing the condition of a step, all of the modifications fall within the scope of the present disclosure.

It is understood that another effect different from that provided by each of the aforementioned embodiments is achieved by the present invention if the effect is obvious from the description and the corresponding drawings in the specification.

What is claimed is:

1. A stacked structure comprising:
a buffer layer and a first semiconductor layer stacked with each other in a vertical direction; and
a second semiconductor layer in contact with a side surface of the first semiconductor layer and surrounding at least a part of the first semiconductor layer in a plane perpendicular to the vertical direction,
wherein each of the first semiconductor layer and the second semiconductor layer includes a Group III-V material or a Group III nitride material,
crystallinity of the first semiconductor layer is higher than crystallinity of the second semiconductor layer, and
the buffer layer is exposed from the second semiconductor layer in the vertical direction.

2. The stacked structure according to claim 1,
wherein the buffer layer and the second semiconductor layer do not overlap each other in the vertical direction.

3. The stacked structure according to claim 1,
wherein the second semiconductor layer is in contact with a side surface of the buffer layer.

4. The stacked structure according to claim 1,
wherein the second semiconductor layer entirely surrounds the first semiconductor layer in the plane.

5. The stacked structure according to claim 1,
wherein a side surface of the second semiconductor layer spaced away from the first semiconductor layer is inclined from the vertical direction.

6. The stacked structure according to claim 5,
wherein a thickness of the second semiconductor layer decreases with increasing distance from the first semiconductor layer in the plane.

7. The stacked structure according to claim 5,
wherein a thickness of the second semiconductor layer increases with increasing distance from the first semiconductor layer in the plane.

8. A semiconductor device comprising a stacked structure comprising:
a first buffer layer and a first semiconductor layer stacked with each other in a vertical direction; and
a second semiconductor layer in contact with a side surface of the first semiconductor layer and surrounding at least a part of the first semiconductor layer in a plane perpendicular to the vertical direction,
wherein each of the first semiconductor layer and the second semiconductor layer includes a Group III-V material or a Group III nitride material,
crystallinity of the first semiconductor layer is higher than crystallinity of the second semiconductor layer, and
the buffer layer is exposed from the second semiconductor layer in the vertical direction.

9. The semiconductor device according to claim 8,
wherein the buffer layer and the second semiconductor layer do not overlap each other in the vertical direction.

10. The semiconductor device according to claim 8,
wherein the second semiconductor layer is in contact with a side surface of the buffer layer.

11. The semiconductor device according to claim 8,
wherein the second semiconductor layer entirely surrounds the first semiconductor layer in the plane.

12. The semiconductor device according to claim 8,
wherein a side surface of the second semiconductor layer spaced away from the first semiconductor layer is inclined from the vertical direction.

13. The semiconductor device according to claim 12,
wherein a thickness of the second semiconductor layer decreases with increasing distance from the first semiconductor layer in the plane.

14. The semiconductor device according to claim 12,
wherein a thickness of the second semiconductor layer increases with increasing distance from the first semiconductor layer in the plane.

15. The semiconductor device according to claim 8 selected from a transistor, a light-emitting element, a photosensor, and a solar battery cell.

16. A fabrication method of a stacked structure, the fabrication method comprising:
forming a buffer layer over a substrate;
forming, over the buffer layer, a semiconductor layer containing gallium nitride so as to cover the buffer layer; and
etching the semiconductor layer so as to leave a first portion of the semiconductor layer overlapping the buffer layer in a vertical direction and a second portion which does not overlap the buffer layer.

17. The fabrication method according to claim 16,
wherein the semiconductor layer is etched so that the second portion surrounds the first portion in a plane perpendicular to the vertical direction.

18. The fabrication method according to claim 16,
wherein the semiconductor layer is formed with a sputtering method.

19. The fabrication method according to claim 16,
wherein the semiconductor layer is etched so that a side surface thereof is inclined from the vertical direction.
